(19) United States
(12) Patent Application Publication
(10) Pub. No.: US 2024/0057389 A1
(43) Pub. Date: Feb. 15, 2024

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Hongying Pan, Shenzhen, Guangdong (CN); Shijian Qin, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 17/754,289

(22) PCT Filed: Feb. 25, 2022
(86) PCT No.: PCT/CN2022/077885

§ 371 Date: Mar. 29, 2022

(30) Foreign Application Priority Data
Feb. 17, 2022 (CN) 202210145844.X

(51) Int. Cl. H10K 59/122; H10K 59/12; H10K 71/13; H10K 59/80

(52) U.S. Cl. CPC H10K 59/122; H10K 59/1201; H10K 71/135; H10K 59/874

(57) ABSTRACT

The present disclosure provides a display panel and a manufacturing method thereof. The display panel includes a substrate and a light-emitting structural layer. The light-emitting structural layer includes a pixel definition layer and a light-emitting functional layer. The pixel definition layer includes a plurality of intersecting dams, and a plurality of printing grooves are defined and surrounded by the dams. The light-emitting functional layer is arranged in the printing grooves. At least one diversion groove is defined on each of the dams. An extension direction of the diversion groove is same as an extension direction of a corresponding one of the dams, and a plurality of the diversion grooves pass through at intersections.

### FIELD OF INVENTION

The present disclosure relates to a field of display technology, and particularly to a display panel and a manufacturing method of the display panel.

### BACKGROUND OF INVENTION

Manufacturing methods of light-emitting functional layers of organic light emitting diode (OLED) display devices generally include two types of vacuum thermal evaporation and ink-jet printing (IJP). Among them, in a preparation of the organic functional layers of the OLED display devices, UP technology has many advantages such as material saving, mild process conditions, and more uniform film formation compared with traditional vacuum thermal evaporation, so it has more application potential.

The UP technology directly drips the ink dissolved with OLED materials into a pre-made pixel definition layer and form a desired pattern after the solvent is volatilized. The pixel definition layer includes dams and a plurality of printing grooves arranged in an array surrounded by the dams, the printing grooves are used to limit the ink, and after drying and baking, the ink limited in the printing grooves forms a thin film.

However, as resolutions of display panels increase, pixels are designed to be smaller and smaller, which corresponds to higher and higher precision requirements of the inkjet printing, and printing precision and ink droplet volume are more and more difficult to control. During a process of the inkjet printing, various external factors, such as deterioration of nozzle stability, may lead to a phenomenon that an ink volume in the printing groove is too large, thus causing the ink in two adjacent printing grooves to be bridged on the dams, which in turn causes mura of the display device.

### Technical Problems

The present disclosure provides a new display panel and a manufacturing method of the display panel, so as to prevent bridging on dams of the ink in two adjacent printing grooves during a manufacturing process.

### Technical Solutions

Technical solutions provided by the present disclosure are as follows:

A display panel, wherein the display panel includes:
a substrate; and
a light-emitting structural layer, disposed on a side of the substrate, and including:
a pixel definition layer, disposed on a side of the substrate and including a plurality of intersecting dams, and a plurality of printing grooves arranged in an array being defined and surrounded by the dams; and
a light-emitting functional layer, arranged in the printing grooves;
wherein at least one diversion groove is defined on each of the dams, and the diversion groove includes an opening on side surfaces of the dams facing away from the substrate, an extension direction of the diversion groove is same as an extension direction of a corresponding one of the dams, and a plurality of the diversion grooves pass through at intersections.

A manufacturing method of a display panel, including:
providing a substrate;
coating a first photoresist layer on the substrate;
photoetching the first photoresist layer to obtain a pixel definition layer, wherein the pixel definition layer includes a plurality of intersecting dams, and a plurality of printing grooves arranged in an array are defined and surrounded by the dams, at least one diversion groove is defined on each of the dams, and the diversion groove includes an opening on side surfaces of the dams facing away from the substrate, an extension direction of the diversion groove is same as an extension direction of a corresponding one of the dams, and a plurality of the diversion grooves pass through at intersections; and
providing a printing ink added with light-emitting functional materials and printing the printing ink in the printing grooves to form a light-emitting functional layer;
wherein the diversion grooves are configured to divert excess ink overflowing from the printing grooves.

### BENEFICIAL EFFECTS

Beneficial effects of the present disclosure are: in the display panel and the manufacturing method of the display panel provided by the present disclosure, diversion grooves passing through with each other are defined on the dams, when an ink volume in a single printing groove is too large and the ink overflows on the dams, the ink will flow into the diversion grooves, that is, the overflowing ink will be diverted away by the diversion grooves, and will not overflow into the adjacent printing grooves, so as to prevent two different inks in the adjacent printing grooves from bridging and causing poor display.

### DESCRIPTION OF DRAWINGS

In order to explain technical solutions in embodiments of the present disclosure more clearly, the following will introduce briefly the drawings used in the description of the embodiments of the present disclosure. Obviously, the drawings in the following description are merely several embodiments of the present disclosure. For those skilled in the art, other drawings can be obtained based on these drawings without creative work.

FIG. 1 is a structural schematic diagram of a display panel provided by an embodiment of the present disclosure.

FIG. 2 is a schematic plan view of a pixel definition layer shown in FIG. 1.

FIG. 3A to FIG. 3F are cross-sectional schematic diagrams of the pixel definition layer shown in FIG. 2 along a line A-A or B-B in various embodiments.

FIG. 4 is a flow chart of a fabrication of a display panel shown in an embodiment of the present disclosure.

FIG. 5 to FIG. 13 are structural schematic diagrams of the display panel shown in an embodiment of the present disclosure during a manufacturing process.

Description of reference numbers and/or reference letters in the drawings is as follows:
display panel 100; substrate 10; base layer 11; driving circuit layer 12; light-emitting structural layer 20; first electrode layer 21; pixel definition layer 22; light-emitting functional layer 23; second electrode layer 24; dam 220; platform surface 2200; first subsection 2201; second subsection 2202; printing groove 221; inner wall 2210; first annular sidewall 2211; second annular sidewall 2212; diversion groove 222; inner wall surface 2221; inner bottom surface 2222; encapsulation layer 30; first photoresist layer P1; second photoresist layer P2; printing ink (Ink).

### DETAILED DESCRIPTION OF EMBODIMENTS

The technical solutions in the embodiments of the present disclosure will be clearly and completely described with reference to the accompanying drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative work fall into protection scope of the present disclosure. Additionally, it should be understood that the specific embodiments described here are merely intended to illustrate and interpret the invention and are not intended to limit the invention. In the present disclosure, without contrary statement, orientational terms such as “up” and “down” are normally used to refer to up and down of the device in actual use or operation, specifically the orientations shown in the drawings; and “inside” and “outside” refer to contours of the device.

The specific embodiments of the display panel provided by the present disclosure will be described below.

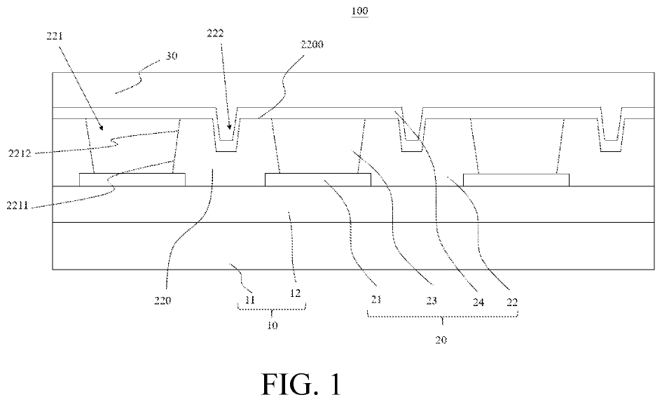

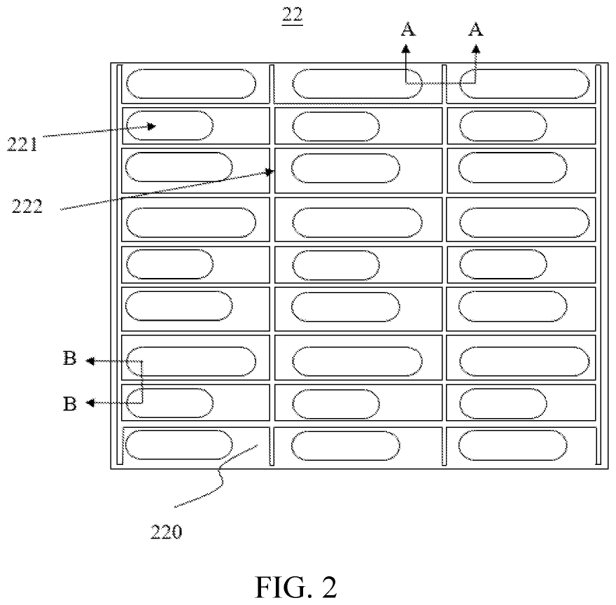

Referring to FIG. 1 and FIG. 2, the present disclosure provides a display panel 100. The display panel 100 includes a substrate 10, a light-emitting structural layer 20, and an encapsulation layer 30. The substrate 10 at least includes a base layer 11 and a driving circuit layer 12 disposed on a side of the base layer 11. The light-emitting structural layer 20 is disposed on a side of the substrate 10. Specifically, the light-emitting structural layer 20 is disposed on a side of the driving circuit layer 12 facing away from the base layer 11 and is electrically connected to the driving circuit layer 12 to achieve luminous function. The encapsulation layer 30 coats the light-emitting structural layer 20 for protecting the light-emitting structural layer 20. It can be understood that FIG. 1 is only a schematic structural diagram of the display panel 100 shown in one of the embodiments of the present disclosure, according to actual requirements, in other embodiments, the substrate 10 may further include other functional layers, such as a light shielding layer, etc., there are no restrictions here.

The light-emitting structural layer 20 includes a first electrode layer 21, a pixel definition layer 22, a light-emitting functional layer 23, and a second electrode layer 24. The pixel definition layer 22 is disposed on a side of the substrate 10 and includes a plurality of intersecting dams 220, and a plurality of printing grooves 221 arranged in an array are defined and surround by the dams 220. The light-emitting functional layer 23 is disposed in the printing grooves 221 to form a plurality of sub-pixel units. The first electrode layer 21 is disposed between the light-emitting functional layer 23 and the substrate 10, that is, the pixel definition layer 22 is disposed on the substrate 10 and the first electrode layer 21, the printing grooves 221 correspond to the first electrode layer 21, and the light-emitting functional layer 23 is disposed on the first electrode layer 21. Specifically, the first electrode layer 21 is disposed on a side of the driving circuit layer 12 facing away from the base layer 11, and the pixel definition layer 22 is disposed on sides of the driving circuit layer 12 and the first electrode layer 21 facing away from the base layer 11. Specifically, the first electrode layer 21 is an anode layer, and the second electrode layer 24 is a cathode layer.

A specific structure (not shown in figures) of the driving circuit layer 12 may adopt a structure in the prior art, at least including a gate metal layer, a gate insulating layer, a source-drain metal layer, and an interlayer insulating layer. The first electrode layer 21 is disposed on the interlayer insulating layer and is electrically connected to the source-drain metal layer. The driving circuit layer 12 merely needs to be able to satisfy its basic functions, and a positional relationship of its specific structure will not be repeated here. It can be understood that, in other embodiments, according to actual requirements, the specific structure of the driving circuit layer 12 may further include other functional layers other than the above, which are not limited here.

A material of the light-emitting functional layer 23 is a printing ink added with light-emitting functional materials, and the printing ink is dropped into the printing grooves 221 through the UP technology, and after a solvent evaporates, sub-pixels of a desired light-emitting functional layer 23 are formed.

At least one diversion groove 222 is defined on each of the dams 220. The diversion groove 222 includes an opening on a side surface of the dam 220 facing away from the substrate 10, that is, the diversion groove 222 is recessed inwardly from a side surface (i.e., a platform surface of the dam 220) of a corresponding one of the dams 220 facing away from the substrate 10. For convenience of subsequent descriptions, it is defined that the side surface of the dam 220 facing away from the substrate 10 is the platform surface 2200. At a same time, an extension direction of the diversion groove 222 is same as an extension direction of the corresponding one of the dams 220, and a plurality of the diversion grooves 222 pass through at intersections, thereby forming a whole through network, which facilitates drainage of overflowing ink when the light-emitting functional layer 23 is printed.

Specifically, the present disclosure does not limit a quantity of the diversion grooves 222 provided on each of the dams 220, which may be one as shown in FIG. 1 and FIG. 2, or two, three, etc., depending on processes and actual needs.

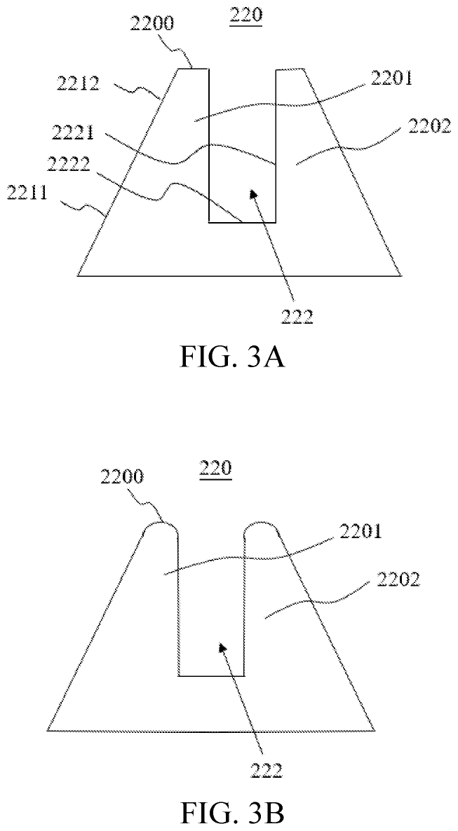

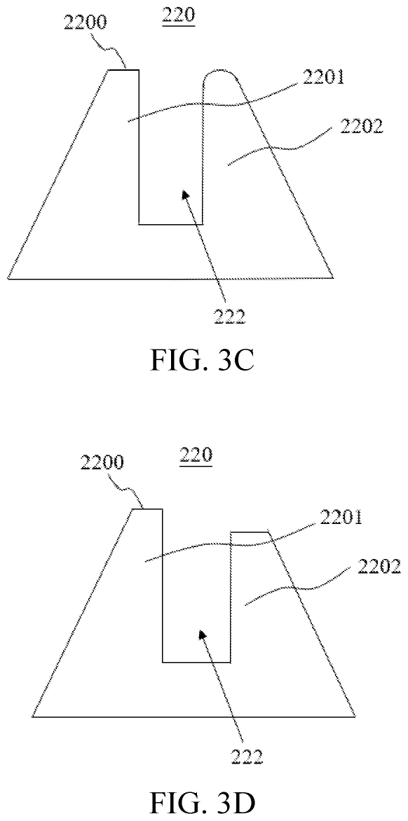

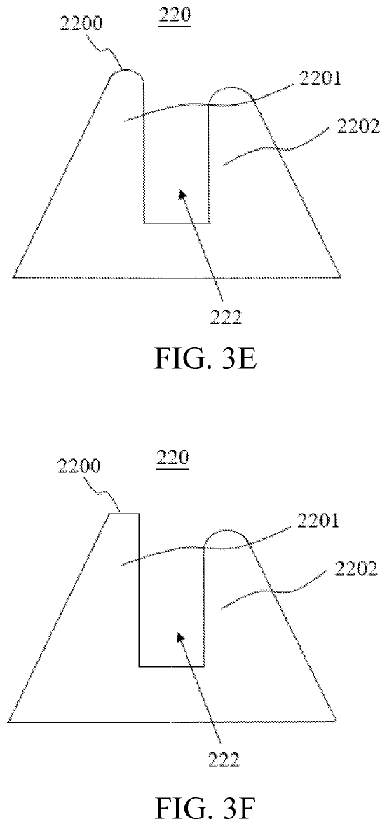

Specifically, the present disclosure does not limit a cross-sectional shape of the diversion groove 222, which may be an inverted trapezoid as shown in FIG. 1, a rectangle as shown in FIG. 3A, or other regular geometric figures or irregular geometric figures not listed, and it mainly depends on the processes and actual needs.

Specifically, in a plane perpendicular to a thickness direction of the display panel 100, as shown in FIG. 2, the extension direction of the diversion groove 222 is defined as a first direction, and a direction perpendicular to the first direction is defined as a second direction; a width of the diversion groove 222 at the opening is defined as a, a width (a total width, including the width a at the opening) of a side of the dam 220 corresponding to the diversion groove 222 facing away from the substrate 10 is defined as b, that is, the width of the diversion groove 222 at the opening corresponding to the second direction is a, and the width of the side of the dam 220 facing away from the substrate 10 in the second direction is b. In the present disclosure, preferably, ⅕≤a/b≤⅓, so that a diversion function of the diversion groove 222 and self-functions of the dams 220 can be ensured at a same time. Specifically, a/b can be equal to ¼, or 4/15, and so on. It can be understood that the widths b of different dams 220 may be same or different, depending on the actual requirements; similarly, the widths a of different diversion grooves 222 may be same or different.

Specifically, a depth of the diversion groove 222 is less than a depth of the printing groove 221, that is, the diversion groove 222 does not penetrate the dam 220, so, during a process of drying the ink, because the ink in the diversion groove 222 is not in contact with the first electrode layer 21 and does not emit light by itself, the ink drying in the diversion groove 222 does not affect a display of the panel. Preferably, in the thickness direction of the display panel 100, a distance between a bottom of the diversion groove 222 and the first electrode 21 is greater than 100 nm.

In the display panel 100 of the present disclosure, the diversion grooves 222 passing through with each other are defined on the dams 220, when the ink volume in a single printing groove 221 is too large and the ink overflows on the dams 220, the ink will flow into the diversion grooves 222, that is, the overflowing ink will be diverted away by the diversion grooves 222, and will not overflow into the adjacent printing grooves 221, so as to prevent two different inks in the adjacent printing grooves 221 from bridging and causing poor display.

FIG. 3A to FIG. 3F are schematic cross-sectional views of the dams 220 of the pixel definition layer 22 in various embodiments of the present disclosure.

Preferably, in some embodiments, the side surface of the dam 220 facing away from the substrate 10, that is, the platform surface 2200, may be a flat surface, or may be a convex arched surface facing away from the substrate 10, as shown in FIG. 3A to FIG. 3F.

Specifically, each of the dams 220 includes a first subsection 2201 and a second subsection 2202 separated by the diversion groove 222. A side surface of the first subsection 2201 facing away from the substrate 10 is a flat surface or a convex arched surface facing away from the substrate 10, and a side surface of the second subsection 2202 facing away from the substrate 10 is a flat surface or a convex arched surface facing away from the substrate 10. Understandably, when the side surfaces of the dams 220 facing away from the substrate 10 are flat, it is beneficial to manufacturing design and can save manufacturing processes compared to an arch design; when the side surfaces of the dams 220 facing away from the substrate 10 are convex arched surfaces facing away from the substrate 10, due to a design of the arched surfaces, when the ink in the printing grooves 221 overflows, a design of climbing and descending slopes increases difficulty of the ink overflowing and ease of the ink flowing into the diversion grooves 222 after overflowing, thereby improving a bad phenomenon of ink bridging to a certain extent.

Specifically, a distance between a vertex of a side of the first subsection 2201 of the dam 220 facing away from the substrate 10 and the substrate 10 and a distance between a vertex of a side of the second subsection 2202 of the dam 220 facing away from the substrate 10 and the substrate 10 may be the same, as shown in FIG. 3A to FIG. 3C, or different, as shown in FIG. 3D to FIG. 3F.

It can be understood that FIG. 3A to FIG. 3F merely show some combination embodiments of the structural features of the dams 220, and other combinations that are not shown but meet the above description are also within the protection scope of the present disclosure.

Referring to FIG. 1 again, preferably, in some embodiments, an inner wall 2210 of the printing groove 221 includes a first annular sidewall 2211 and a second annular sidewall 2212 connected with each other. The first annular sidewall 2211 is close to the substrate 10 and its surface is hydrophilic, the second annular sidewall 2212 is away from the substrate 10 and its surface is hydrophobic, that is, a surface material of the first annular sidewall 2211 is a hydrophilic material, and a surface material of the second annular sidewall 2212 is a hydrophobic material. It should be noted that, because a surface difference between the first annular sidewall 2211 and the second annular sidewall 2212 merely lies in hydrophilicity and hydrophobicity, which cannot be seen from external expression structures, therefore, there is no clear boundary distinction between the first annular sidewall 2211 and the second annular sidewall 2212 in the figures.

It is well known that in the OLED display devices in prior art, the ink used in the inkjet printing is organic materials dissolved in a solvent of lipids or alcohols, and it has two properties: water-based and oil-based, and during the manufacturing process, the ink needs to be dried, and the dried ink should spread evenly on the substrate 10. A material that is hydrophilic means the ink can have a smaller contact angle on the material and is easy to level; a material that is hydrophobic means the ink will have a large contact angle on the material and is not easy to spread. Therefore, only a hydrophilic material can make the ink dry on the material to maintain a film with a uniform thickness. When the ink dries on a hydrophobic material, protrusions will be formed, which will seriously affect a uniformity of the film thickness.

In the embodiment, a surface of the first annular sidewall 2211 of the printing groove 221 close to the substrate 10 is hydrophilic, so that the printing ink can be quickly spread in the printing groove 221, and it is beneficial to maintain the uniformity of the film thickness after drying. At a same time, in the embodiment, a surface of the second annular sidewall 2212 of the printing groove 221 away from of the substrate 10 is hydrophobic, so that an accumulation effect of the printing ink in the printing groove 221 is enhanced, and the bad phenomenon of the ink bridging is improved to a certain extent.

Preferably, in some embodiments, the surfaces (i.e., the platform surfaces 2200) of the dams 220 facing away from the substrate 10 have hydrophobicity. That is, materials of the surfaces of the dams 220 facing away from the substrate 10 are hydrophobic materials. In this way, when the ink in the printing grooves 221 overflows, the ink has large contact angles with the surfaces of the dams 220 facing away from the substrate 10, so it will not overflow quickly, thereby preventing the overflowing ink from overflowing into the adjacent printing grooves 221 due to too fast flow rate, which improves the bad phenomenon of ink bridging to a certain extent.

Preferably, in some embodiments, inner wall surfaces 2221 and inner bottom surfaces 2222 of the diversion grooves 222 are all hydrophilic. That is, surface materials of the inner walls and the inner bottoms of the diversion grooves 222 are both hydrophilic materials. It is designed in this way that when the ink in the printing grooves 221 overflows, the ink overflows the surfaces of the dams 220 facing away from the substrate 10, and then flows instantaneously and smoothly in the diversion grooves 222, to prevent the overflowing ink from overflowing into the adjacent printing grooves 221, which further improves the bad phenomenon of the ink bridging.

In order to realize the above-mentioned hydrophilic and hydrophobic design, in an embodiment, the dams 220 are made of a hydrophilic photoresist material. The hydrophilic photoresist material is formed by mixing a resin, a sensitizer, and a solvent, and hydrophilic groups are added into the resin. The hydrophilic groups here can be ether bonds composed of oxygen-containing groups, hydroxyl groups and carboxylate esters, block polyethers, etc., which are not specifically limited, as long as basic functions can be satisfied. In addition, during the manufacturing process, in order to realize a hydrophobic design of the surface of the second annular sidewall 2212, the second annular sidewall 2212 is subjected to a plasma surface treatment containing fluorine ions or fluorine groups. The plasma containing fluorine ions or fluorine groups will bombard the surface of the photoresist material during the plasma surface treatment. At this time, the old bonds will break and new bonds will be formed on the photoresist surface, which will allow the fluorine groups or the fluorine ions to form bonding energy with the photoresist. In this way, the surface of the second annular sidewall 2212 has the fluoride ions or the fluorine groups, and exhibits hydrophobic and oleophobic properties, that is, hydrophobic properties.

It can be understood that, in other embodiments, the dams 220 can also be made of other alternative materials, as long as final requirements can be met. Similarly, the material of the dams 220 can also be made of hydrophobic materials, and then part of the surfaces can be made hydrophilic through a surface treatment, which is also within the scope of protection of the present disclosure.

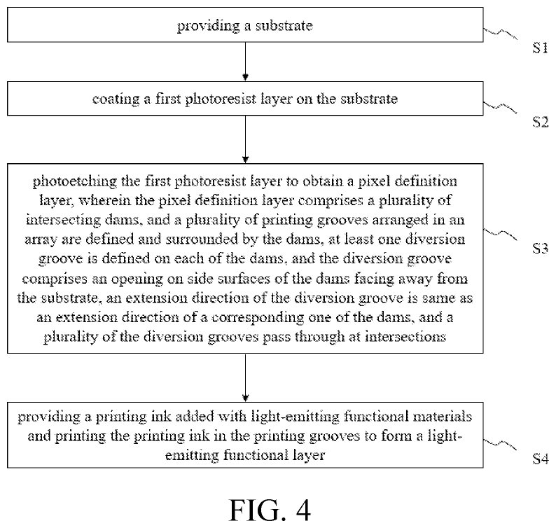

Referring to FIG. 4, the present disclosure further provides a manufacturing method of the above-mentioned display panel 100, the manufacturing method at least includes the following steps:
S1, providing a substrate;
S2, coating a first photoresist layer on the substrate;
S3, photoetching the first photoresist layer to obtain a pixel definition layer, wherein the pixel definition layer includes a plurality of intersecting dams, and a plurality of printing grooves arranged in an array are defined and surrounded by the dams, at least one diversion groove is defined on each of the dams, and the diversion groove includes an opening on side surfaces of the dams facing away from the substrate, an extension direction of the diversion groove is same as an extension direction of a corresponding one of the dams, and a plurality of the diversion grooves pass through at intersections; and
S4, providing a printing ink added with light-emitting functional materials and printing the printing ink in the printing grooves to form a light-emitting functional layer.

Specifically:

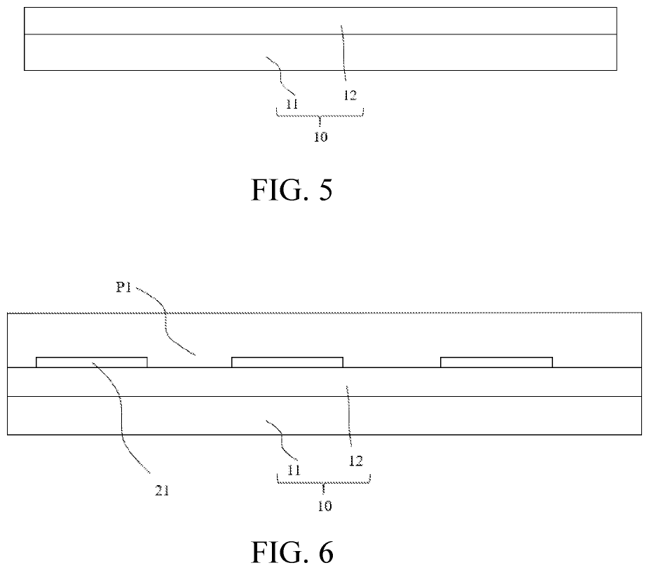

Referring to FIG. 5, in the step S1, a substrate 10 is provided. The substrate 10 is a substrate that has undergone a pre-process, which at least includes a base layer 11 and a driving circuit layer 12 disposed on a side of the base layer 11.

Referring to FIG. 6, in the step S2, a first photoresist layer P1 is coated on the substrate 10. It can be understood that, before the step S2, the manufacturing method includes fabricating a patterned first electrode layer 21 on the substrate 10.

Specifically, a specific structure (not shown in figures) of the driving circuit layer 12 may adopt a structure in the prior art, at least including a gate metal layer, a gate insulating layer, a source-drain metal layer, and an interlayer insulating layer. The first electrode layer 21 is disposed on the interlayer insulating layer and is electrically connected to the source-drain metal layer. The driving circuit layer 12 merely needs to be able to satisfy its basic functions, and the positional relationship of its specific structure is not repeated here. It can be understood that, in other embodiments, according to actual requirements, the specific structure of the driving circuit layer 12 may further include other functional layers other than the above, which are not limited here.

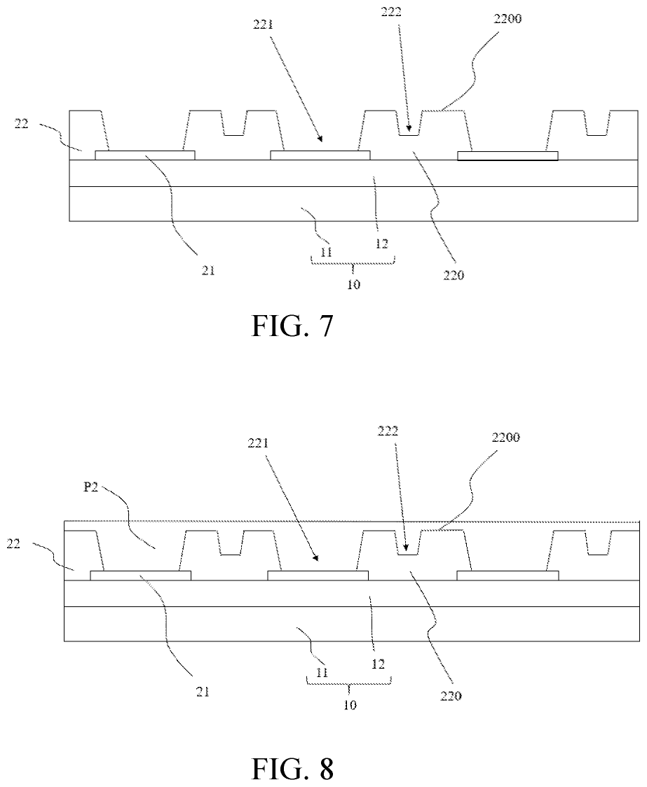

Referring to FIG. 7, in the step S3, the first photoresist layer P1 is photoetched to obtain a pixel definition layer 22. Wherein, the pixel definition layer 22 includes a plurality of intersecting dams 220, and a plurality of printing grooves 221 arranged in an array are defined and surround by the dams 220, at least one diversion groove 222 is defined on each of the dams 220, and the diversion groove 222 includes an opening on a side surface of the dam 220 facing away from the substrate 10, that is, the diversion groove 222 is recessed inwardly from a side surface of a corresponding one of the dams 220 facing away from the substrate 10. An extension direction of the diversion groove 222 is same as an extension direction of a corresponding one of the dams 220, and a plurality of the diversion grooves 222 pass through at intersections. Specifically, in the embodiment, when the first photoresist layer P1 is photoetched to form the pixel definition layer 22, a photoetching process is completed by one mask etching process, and the photoetching process may be a halftone mask etching process, or may be a grayscale mask etching process. It can be understood that, according to actual manufacturing environment, the aforementioned one mask etching process can also be divided into two mask etching processes to complete. For example, a patterned etching of the printing grooves 221 is completed first through a first mask etching process, and then a patterned etching of the diversion grooves 222 is completed through a second mask etching process.

Specifically, before the photoetching process, according to the manufacturing process and actual demands, it is necessary to design a quantity, structures, and sizes of the dams 220, the printing grooves 221, and the diversion grooves 222 in advance. After the photoetching process is completed, the quantity, the structures, and the sizes of the dams 220, the printing grooves 221, and the diversion grooves 222 are same as the structures in the display panel 100 described above and will not be repeated here.

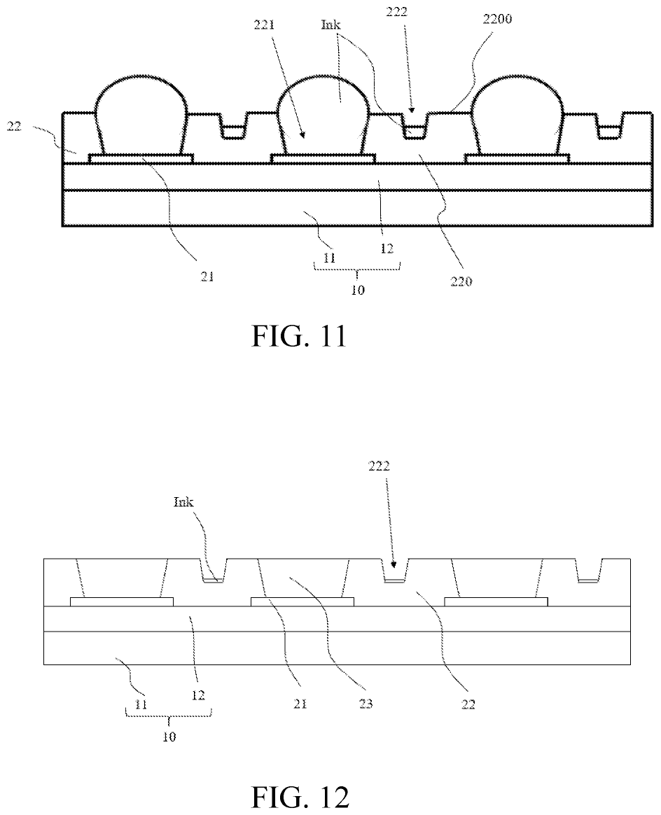

Referring to FIG. 11 and FIG. 12, in the step S4, the printing ink (Ink) added with the luminescent functional materials is provided and the printing ink (Ink) is printed in the printing grooves 221 to form the light-emitting functional layer 23.

Specifically, during the manufacturing process, the printing ink (Ink) is firstly dripped into the printing grooves 221 by using the UP technology, and during the dripping process, the printing ink (Ink) that overflows the printing grooves 221 flows into the diversion grooves 222, as shown in FIG. 11; the printing ink (Ink) of the printing grooves 221 is then dried to form the light-emitting functional layer 23. It can be understood that during a drying process, the solvent of the printing ink (Ink) flowing into the diversion grooves 222 is also evaporated, but because the printing ink (Ink) in the diversion grooves 222 is not in contact with the first electrode layer 21 and it does not emit light by itself, the drying of the printing ink (Ink) in the diversion grooves 222 does not affect the display of the panel.

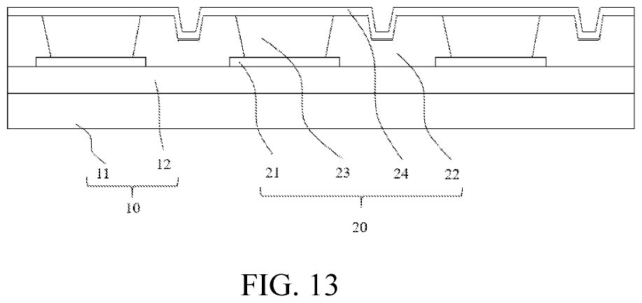

Referring to FIG. 13 and FIG. 1, after the step S4, the manufacturing method further includes forming a second electrode layer 24 on the pixel definition layer 22 and the light-emitting functional layer 23 and forming an encapsulation layer 30 on the second electrode layer 24. Specifically, the second electrode layer 24 is deposited on the pixel definition layer 22, on the light-emitting functional layer 23, and in the diversion grooves 222, and the encapsulation layer 30 planarizes the diversion grooves 222.

It is well known that, in the OLED display devices in prior art, the ink used in the inkjet printing is that organic materials dissolved in a solvent of lipids or alcohols, and there are two properties of water-based and oily, and during the manufacturing process, the ink needs to be dried, and the dried ink should be spread evenly on the substrate 10. That a material is hydrophilic means the ink can have a smaller contact angle on the material and is easy to level; That a material is hydrophobic means the ink will have a large contact angle on the material and is not easy to spread. Therefore, only a hydrophilic material can make the ink dry on the material to maintain a film with a uniformity thickness. When the ink dries on a hydrophobic material, protrusions will be formed, which will seriously affect a uniformity of the film thickness.

Therefore, in the embodiment, the first photoresist P1 is made of a hydrophilic photoresist material. Thus, a surface of the first annular sidewall 2211 of the printing groove 221 close to the substrate 10 is hydrophilic, so that the printing ink can be quickly spread in the printing grooves 221, and it is beneficial to maintain the uniformity of the film thickness after drying. At a same time, in the embodiment, inner side surfaces 2221 and inner bottom surfaces 2222 of the diversion grooves 222 are all hydrophilic. When the ink in the printing grooves 221 overflows, the ink overflows the surfaces of the dams 220 facings away from the substrate 10 and is then instantly leveled in the diversion grooves 222 to prevent the overflowing ink from overflowing into the adjacent printing grooves 221, which further improves the bad phenomenon of the ink bridging.

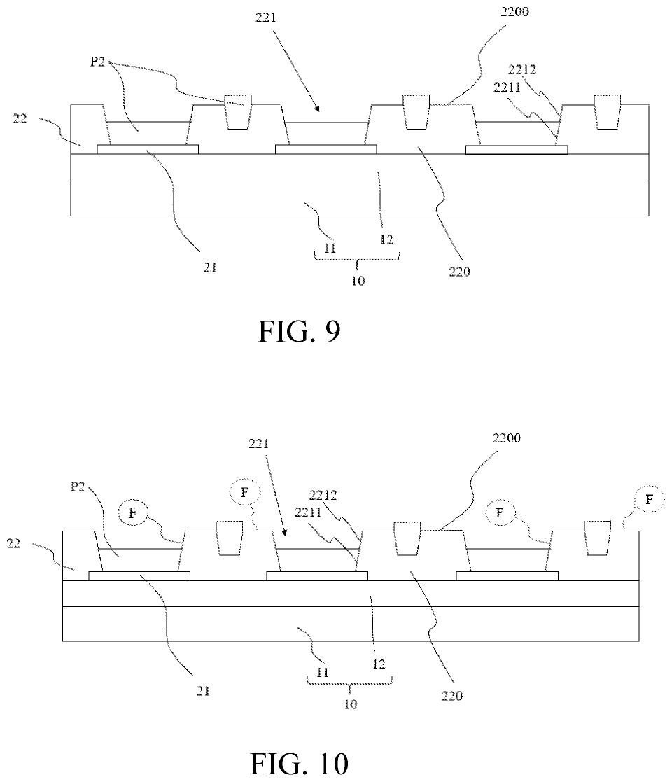

Understandably, in order to further improve the undesirable phenomenon of the ink bridging, the present embodiment also includes steps after the step S3 and before the step S4:
S301, referring to FIG. 8, a second photoresist layer P2 is coated on the pixel definition layer 22, wherein a polarity of the second photoresist layer P2 is inverse to a polarity of the first photoresist layer P1;
S302, referring to FIG. 9, the second photoresist layer P2 is photoetched to expose the side surfaces (that is, the above-mentioned platform surface 2200) of the dams 220 facing away from the substrate 10 and to expose part of the inner sidewall surfaces (i.e., surfaces of the second annular sidewalls 2212 of the above-mentioned display panel 100) of the printing grooves 221 away from the substrate 10;
S303, referring to FIG. 10, the side surfaces of the dams 220 facing away from the substrate 10 and the surfaces of the second annular sidewalls 2212 are subjected to a plasma surface treatment containing fluorine ions or fluorine groups to make the side surfaces of the dams 220 facing away from the substrate 10 and the surfaces of the second annular sidewalls 2212 hydrophobic; and
S304, referring to FIG. 11, a remaining part of the second photoresist layer P2 is peeled off.

The processes of above-mentioned step S301 to step S304 are carried out before the step S4 of the inkjet printing, which makes the surfaces of the second annular sidewalls 2212 of the printing grooves 221 away from of the substrate 10 hydrophobic after the surface treatment. It enhances an accumulation effect of the printing ink in the printing grooves 221 and improves the bad phenomenon of the ink bridging to a certain extent. At a same time, the side surfaces (i.e., the platform surface 2200) of the dams 220 facing away from the substrate 10 are also hydrophobic after the surface treatment. When the ink in the printing grooves 221 overflows, the ink has a large contact angle with the side surfaces of the dams 220 facing away from the substrate 10, so it will not overflow quickly, thereby preventing the overflowing ink from overflowing into the adjacent printing grooves 221 due to the too fast flow rate, which improves the bad phenomenon of the ink bridging to a certain extent.

It can be understood that, in other embodiments, the dams 220 can also be made of other alternative materials, as long as the final requirements can be met. Similarly, the material of the dams 220 can also be made of hydrophobic materials, and then part of the surfaces can be made hydrophilic through a surface treatment, which is also within the scope of protection of the present disclosure.

In summary, although the present disclosure has been disclosed as above in preferred embodiments, the above-mentioned preferred embodiments are not intended to limit the present disclosure. Those of ordinary skills in the art, without departing from the spirit and scope of the present disclosure, various changes and modifications can be made, so the protection scope of the present disclosure is subject to the scope defined by the claims.

What is claimed is:

1. A display panel, wherein the display panel comprises:
a substrate; and
a light-emitting structural layer, disposed on a side of the substrate, and comprising:
a pixel definition layer, disposed on a side of the substrate and comprising a plurality of intersecting dams, and a plurality of printing grooves arranged in an array being defined and surrounded by the dams; and
a light-emitting functional layer, arranged in the printing grooves;
wherein at least one diversion groove is defined on each of the dams, and the diversion groove comprises an opening on side surfaces of the dams facing away from the substrate, an extension direction of the diversion groove is same as an extension direction of a corresponding one of the dams, and a plurality of the diversion grooves pass through at intersections.

2. The display panel according to claim 1, wherein a material of the light-emitting functional layer is a printing ink added with light-emitting functional materials, and all of inner wall surfaces and inner bottom surfaces of the diversion grooves are hydrophilic.

3. The display panel according to claim 2, wherein the side surfaces of the dams facing away from the substrate are hydrophobic.

4. The display panel according to claim 2, wherein an inner wall of each of the printing grooves comprises a first annular sidewall and a second annular sidewall, the first annular sidewall is close to the substrate and its surface is hydrophilic, and the second annular sidewall is away from the substrate and its surface is hydrophobic.

5. The display panel according to claim 4, wherein a material of the dams is a hydrophilic photoresist, and a surface of the second annular sidewall and the side surfaces of the dams facing away from the substrate are surface-treated to contain fluorine ions or fluorine groups.

6. The display panel according to claim 1, wherein a width of the diversion groove at the opening is a, and a width of a side of one of the dams corresponding to the diversion groove facing away from the substrate is b, wherein ⅕≤a/b≤⅓.

7. The display panel according to claim 1, wherein each of the dams comprises a first subsection and a second subsection separated by the diversion groove, a distance between a side of the first subsection facing away from the substrate and the substrate is less than a distance between a side of the second subsection facing away from the substrate and the substrate.

8. The display panel according to claim 1, wherein each of the dams comprises a first subsection and a second subsection separated by the diversion groove, a side surface of the first subsection facing away from the substrate is a flat surface or a convex arched surface facing away from the substrate, and a side surface of the second subsection facing away from the substrate is a flat surface or a convex arched surface facing away from the substrate.

9. The display panel according to claim 1, wherein a depth of the diversion groove is less than a depth of any one of the printing grooves.

10. The display panel according to claim 9, wherein the light-emitting structural layer further comprises a first electrode layer, the first electrode layer is disposed on the substrate, and the pixel definition layer is disposed on the substrate and the first electrode layer, and in a thickness direction of the display panel, a distance between a bottom of the diversion groove and the first electrode layer is greater than 100 nm.

11. A display panel, wherein the display panel comprises:
a substrate; and
a light-emitting structural layer, disposed on a side of the substrate, and comprising:
a pixel definition layer, disposed on a side of the substrate and comprising a plurality of intersecting dams, and a plurality of printing grooves arranged in an array being defined and surrounded by the dams; and
a light-emitting functional layer, arranged in the printing grooves;
wherein side surfaces of the dams facing away from the substrate are hydrophobic, at least one diversion groove is defined on each of the dams, and the diversion groove comprises an opening on the side surfaces of the dams facing away from the substrate, an extension direction of the diversion groove is same as an extension direction of a corresponding one of the dams, and a plurality of the diversion grooves pass through at intersections.

12. The display panel according to claim 11, wherein an inner wall of each of the printing grooves comprises a first annular sidewall and a second annular sidewall, the first annular sidewall is close to the substrate and its surface is hydrophilic, and the second annular sidewall is away from the substrate and its surface is hydrophobic.

13. The display panel according to claim 12, wherein a material of the light-emitting functional layer is a printing ink added with light-emitting functional materials, and all of inner wall surfaces and inner bottom surfaces of the diversion grooves are hydrophilic.

14. The display panel according to claim 12, wherein a material of the dams is a hydrophilic photoresist, and a surface of the second annular sidewall and the side surfaces of the dams facing away from the substrate are surface-treated to contain fluorine ions or fluorine groups.

15. The display panel according to claim 13, wherein a material of the dams is a hydrophilic photoresist, and a surface of the second annular sidewall and the side surfaces of the dams facing away from the substrate are surface-treated to contain fluorine ions or fluorine groups.

16. A manufacturing method of a display panel, comprising:
providing a substrate;
coating a first photoresist layer on the substrate;
photoetching the first photoresist layer to obtain a pixel definition layer, wherein the pixel definition layer comprises a plurality of intersecting dams, and a plurality of printing grooves arranged in an array are defined and surrounded by the dams, at least one diversion groove is defined on each of the dams, and the diversion groove comprises an opening on side surfaces of the dams facing away from the substrate, an extension direction of the diversion groove is same as an extension direction of a corresponding one of the dams, and a plurality of the diversion grooves pass through at intersections; and
providing a printing ink added with light-emitting functional materials and printing the printing ink in the printing grooves to form a light-emitting functional layer;
wherein the diversion grooves are configured to divert excess ink overflowing from the printing grooves.

17. The manufacturing method of the display panel according to claim 16, wherein the first photoresist layer is hydrophilic, an inner wall of each of the printing grooves comprises a first annular sidewall and a second annular sidewall, the first annular sidewall is close to the substrate, and the second annular sidewall is away from the substrate, before the step of providing the printing ink added with the light-emitting functional materials and printing the printing ink in the printing grooves to form the light-emitting functional layer, the manufacturing method further comprise steps of:
coating a second photoresist layer on the pixel definition layer, wherein a polarity of the second photoresist layer is inverse to a polarity of the first photoresist layer;
photoetching the second photoresist layer to expose the side surfaces of the dams facing away from the substrate and to expose a surface of the second annular sidewall;
subjecting the side surfaces of the dams facing away from the substrate and the surface of the second annular side wall to a plasma surface treatment containing fluorine ions or fluorine groups to make the side surfaces of the dams facing away from the substrate and the surface of the second annular side wall hydrophobic; and
removing a remaining part of the second photoresist layer.
